(19) United States
(12) Patent Application Publication
(10) Pub. No.: US 2006/0199328 A1
(43) Pub. Date: Sep. 7, 2006

(54) Non-dispersive high density polysilicon capacitor utilizing amorphous silicon electrodes

(75) Inventors: Maxwell W. Lippitt III, Rockwall, TX (US); Byron L. Williams, Plano, TX (US); Michael J. DuBois, Richardson, TX (US); Betty S. Mercer, Plano, TX (US); Scott K. Montgomery, Rowlett, TX (US); C. Matthew Thompson, Highland Village, TX (US); Evelyn Lafferty, Frisco, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/072,186

(22) Filed: Mar. 4, 2005

(51) Int. Cl. H01L 21/8232

(52) U.S. Cl. 438/239; 438/253; 438/396

(57) ABSTRACT

The present invention provides, in one aspect, a method of fabricating a capacitor 615, comprising forming a first electrode 610, placing a dielectric 515 over the first electrode, and locating a second electrode 510 over the dielectric wherein at least one of the first or second electrodes 610, 510 is doped amorphous silicon.

### TECHNICAL FIELD OF THE INVENTION

The present invention is directed in general to a microelectronics device and a method for its manufacture that includes a capacitor, and more specifically, to a microelectronics device that includes a capacitor that has at least one electrode fabricated from amorphous silicon.

### BACKGROUND

Microelectronic circuits have become practicably indispensable in present day electronic devices, and their use can vary over a broad range of applications. For example, they are frequently used in radio frequency (RF) and analog circuits. In RF circuits, linear capacitors are used, typically along with inductors, to define or set a critical operating frequency of the RF circuit. Similarly, capacitors are used in analog circuits, typically along with resistors, to provide a high pass or low pass filter component for the microelectronics circuit. These devices provide greater benefits in that they provide accurate operating frequency or filter parameters for the microelectronics circuits in which they are used. In these, as well as other types of circuits, it is very important that the capacitors be as linear as possible. In other words, it is highly desirable that the capacitance is as flat as possible with respect to the voltage so that the capacitance doesn't vary over the operating voltage of the device.

For example, in an RF circuit, it is highly advantageous to have a fixed value of capacitance and a fixed value for inductance, which are used to define the critical operating frequency of the RF circuit. As such, it is important that the capacitance of the capacitor and the inductance of the inductor stay as constant as possible. For analog circuits, the requirements are similar because the capacitor is used in a filter circuit, so the critical frequency in the filter is set by the capacitance and inductance, which is usually a combination of a resistor and a capacitor. If the critical frequency changes or fluctuates, the characteristics of the analog circuit will also be affected. Thus, it can be seen that in these types of devices it is very beneficial that the capacitor be as linear and non-dispersive as possible to assure proper operation of the circuit.

Presently, the electrodes for these capacitors are constructed from either metal or polysilicon, both of which suffer from different shortcomings. While metal provides low resistance and consistent, linear capacitance, there are certain negative manufacturing aspects associated with its use. In many process flows, it is highly advantageous that any new process easily integrate into existing process flows. This not only results in cost savings, but also minimizes any variables that might be introduced by way of the new process. One significant disadvantage associated with using a metal plate in the capacitor is that the processes used to form the metal electrodes require at least another level of metal, which consequently includes additional masks and a number of additional processing steps. Moreover, because of the thermal budgets involved, they may not be able to be manufactured at the device level. These drawbacks not only can drive up manufacturing costs, but they can add a number or variables to the process, and therefore, greater complexity, neither of which are desirable.

To avoid the problems associated with metal, many manufacturers have turned to forming the capacitor electrodes from doped polysilicon. Polysilicon is more desirable from a manufacturing standpoint because it can be used at the device level, thereby potentially reducing the numbers of masks and overall complexity of the capacitor's incorporation into the microlectronics circuits. Additionally, since many gate structures are comprised on polysilicon, the use of polysilicon to form the electrodes allows easy integration into existing process flows. Unfortunately, however, polysilicon suffers from its own disadvantages, which from a manufacturing standpoint, essentially offset the above-mentioned advantages.

One such disadvantage arises in the crystalline nature of the polysilicon itself. Polysilicon is typically formed at a temperature of about 620 degrees centigrade, and at this temperature, a poly grained silicon material is formed that has an extensive grain boundary network located between the grains. Due to the presence of these grain boundaries, much of the dopant that is implanted into the polysilicon that gives rise to its conductivity can be lost or bound up within the grain boundaries. As such, the trapped or bound dopant is not available for activation, which means that it won't lend to the conductivity of the polysilicon. This, in turn, increases the resistance of the polysilicon and the non-linearity or dispersive nature of the capacitor in general. Lack of linearity results in distortion of signals and can be up converted to higher frequencies in mixers and nonlinear circuits. As such, the capacitance of the polysilicon capacitor can fluctuate with voltage, thereby causing the circuit function outside prescribed parameters.

Accordingly, what is needed in the art is a capacitor that does not suffer the disadvantages associated with the devices discussed above.

### SUMMARY OF INVENTION

To address the above-discussed deficiencies of the prior art, the present invention provides, in one embodiment, a method of fabricating a capacitor, comprising forming a first electrode, placing a dielectric over the first electrode, and locating a second electrode over the dielectric, wherein at least one of the first or second electrodes is formed from a doped amorphous silicon.

In another embodiment, the present invention includes a method of fabricating an integrated circuit. This particular embodiment comprises forming transistors over a microelectronics substrate, placing capacitors over the microelectronics substrate, which further comprises forming a first electrode, placing a capacitor dielectric over the first electrode, and locating a second electrode over the dielectric, wherein at least one of the first or second electrodes is formed from a doped amorphous silicon. Dielectric layers are deposited over the transistors and capacitors, and interconnects are formed within the dielectric layers to interconnect the transistors and the capacitors to form an operative integrated circuit.

The foregoing has outlined preferred and alternative features of the present invention so that those of ordinary skill in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the scope. of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features may not be drawn to scale. In fact, the dimensions of the various features may be arbitrarily increased or reduced for clarity of discussion. Reference is now made to the following descriptions taken in conjunction with the accompanying drawings, in which:

FIG. 1 illustrates a partial sectional view of one embodiment of a microelectronics device at an intermediate point of manufacture generally showing the capacitor, as provided by the present invention, adjacent conventional transistors;

FIG. 2 illustrates a partial sectional view of a microelectronics device at an early stage of manufacture;

FIG. 3 illustrates a partial sectional view of the microelectronic device of FIG. 2 following the deposition of a capacitor dielectric layer;

FIG. 4 illustrates a partial sectional view of the microelectronics device of FIG. 3 following the deposition and doping of a second layer from which the second electrode of the capacitor will be formed;

FIG. 5 illustrates a partial section view of the microelectronics device of FIG. 4, following the patterning of the second layer and the capacitor dielectric layer to form an upper electrode and capacitor dielectric of a capacitor;

FIG. 6 illustrates a partial section view of the microelectronics device of FIG. 5, after the formation of the gate layer to form a first electrode of a completed capacitor and gate of a partially completed transistor;

FIG. 7 illustrates a partial sectional view of a multi-layered integrated circuit design incorporating the capacitor provided by the present invention;

FIG. 8 is a graph of the capacitance versus voltage of a capacitor constructed using prior art process and materials and a capacitor made in accordance with an embodiment of the present invention; and

FIG. 9 is a bar graph comparing the linear voltage capacitance coefficients (VCC) of different capacitors having at least one electrode fabricated from amorphous silicon using differing dopant dosages and implant powers, with a conventional capacitor having electrodes only made from polysilicon.

### DETAILED DESCRIPTION

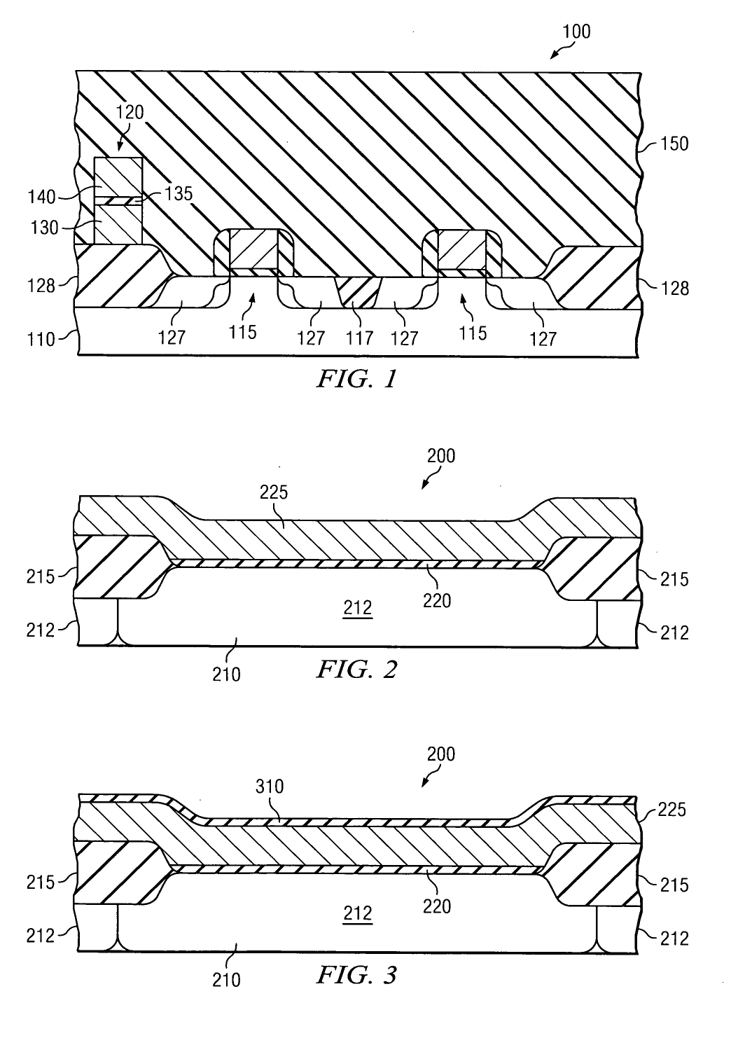

Turning initially to FIG. 1, there is illustrated a partial sectional view of one embodiment of a microelectronics device 100 at an intermediate point of manufacture, as provided by the present invention. It should be noted at the outset that the layout and design of the microelectronics device 100 is illustrative only and the present invention may be employed in a number of various microelectronics device configurations and particularly those that require the use of a highly linear, non-dispersive capacitor. In this particular embodiment, the exemplary microelectronics device 100 includes a substrate 110, examples of which include semiconductive substrates, such as doped silicon. However, other materials that can be employed to build microelectronic devices may also be used. The microelectronics device 100 also includes conventional transistors 115 located on the substrate 110, which are isolated by an isolation structure 117. Each transistor 115 also includes source/drain regions 127 that may further comprise lightly doped drain (LDD) regions and halo regions, which are not individually designated. The illustration of the embodiment of FIG. 1 also includes a capacitor 120 located at the gate level and that is located on field oxide 128.

The capacitor 120 includes a first electrode 130, a capacitor dielectric 135 and second electrode 140. In an advantageous embodiment, at least one, if not both, of the first and second electrodes 120, 140 are formed from a doped amorphous silicon. In the illustrated exemplary embodiment, the second electrode 140 has been formed from an amorphous silicon that is doped and subsequently annealed. This provides advantages over conventional processes and devices because unlike polysilicon, amorphous silicon is essentially non-crystalline and has little or no grain boundaries associated with its structure. As such, when the dopant is implanted into the amorphous silicon, it does not get trapped by the grain boundaries and more dopant is available for activation. In turn, this provides an electrode that has less resistance and is not as dispersive as doped polysilicon, which results in a capacitor that has more consistent, linear capacitance. Such capacitors are well suited for RF and analog applications that require a non-dispersive, linear capacitor.

Another advantage of the embodiment of FIG. 1 resides in the fact that the amorphous silicon electrode can easily be incorporated into polysilicon gate processing schemes, thereby allowing for ease of integration into existing process flows with minimal process variation and cost. However, it should be noted that the capacitor may be fabricated at any level within the microelectronic device 100, and is therefore, not limited to just the gate level. With a general overview having been discussed, an advantageous process embodiment, and variations thereof, for manufacturing the capacitor 120 will now be discussed.

Turning next to FIG. 2, there is illustrated a partial sectional view of a microelectronics device 200 at an early stage of manufacture. As was the case with FIG. 1, it should be kept in mind that the configuration the device of FIG. 2, as well as the following figures, are illustrative only. At this point of manufacture, the microelectronics device 200 includes a microelectronics substrate 210, such as a conventionally doped epitaxial layer or doped silicon base wafer, in which wells or tubs 212 can be formed. Conventionally formed field oxide regions 215 and a gate oxide layer 220 are also included. Located over the microelectronics substrate 210 and the field oxide regions 215 is a gate layer 225, such as a polysilicon layer, shown subsequent to a conventional masking and doping process. The gate layer 225 is initially blanket deposited over the microelectronics substrate 200 and gate oxide 220. In one embodiment, the gate layer 225 is conventionally deposited with conventional materials, such as silane. The thickness of the gate layer 225 may vary, depending on design parameters. For example, the gate layer 225 may have a thickness of about 200 nm. Due to the fact that the gate layer 225 is located on the device level, the gate layer 225 can be advantageously used to form both the lower electrode of a later formed capacitor and the gate for an adjacent transistor.

In those embodiments where the microelectronics device 200 is intended to be a complementary metal oxide semiconductor (CMOS) device, the microelectronics device 200 is patterned to expose the gate layer 225 within an N-type region of the CMOS device and is then conventionally implanted with an N-type dopant, such as phosphorous or arsenic. This is followed by the converse patterning of the microelectronic device 200 to expose the gate layer 225 within a P-type region of the CMOS device, which is implanted with a P-type dopant, such as boron. The formation of a CMOS layout, such as the one just mentioned, is well known to those who are skilled in the art. It should be noted that FIG. 2 shows only one portion of the microelectronic device 200 where the gate layer 225 has been doped in the conventional manner described above. Following the implantation of the gate layer 225, the patterned mask is stripped and the microelectronics device 200 is subjected to a conventional clean process, which is followed by a conventional anneal to activate the dopant in the gate layer 225

In an alternative embodiment, the gate layer 225 may be deposited as an amorphous silicon material instead of a polysilicon material. In such embodiments, the amorphous layer can be formed, for example, by flowing silane gas over the microelectronic device substrate 200 at a temperature ranging from about 510 degrees centigrade to about 580 degrees centigrade. Those skilled in the art understand that other deposition parameters, such as flow rates and pressures, may vary as well. When amorphous material is used in place of polysilicon, its attendant advantages, which are discussed below, can further enhance the linearity of the capacitors due to the fact that the amorphous silicon layer can then be used to form the lower electrode of the capacitor. The amorphous silicon material is subsequently doped and annealed to activate the dopants. The dosage of the dopant and the powers used to implant are preferably the same as those discussed below with respect to the second layer used to form the second capacitor electrode. However, in another embodiment, one layer may require more dopant than another to achieve the lowest VCC.

Turning now to FIG. 3, there is illustrated a partial sectional view of the microelectronic device 200 following the deposition of a capacitor dielectric layer 310. The process and materials used to form the capacitor dielectric layer 310 can be conventional. For example, the capacitor dielectric layer 310 may comprise a silicon oxide material, such as silicon dioxide, or it may comprise a silicon nitride. In exemplary embodiments, however, the capacitor dielectric layer 310 is silicon dioxide or silicon nitride. Other well known dielectric materials may also be used. The thickness of the capacitor dielectric layer 310 may vary, depending on the desired capacitance density and the operating voltage. For example, its thickness may range from about 25 nm to about 350 nm.

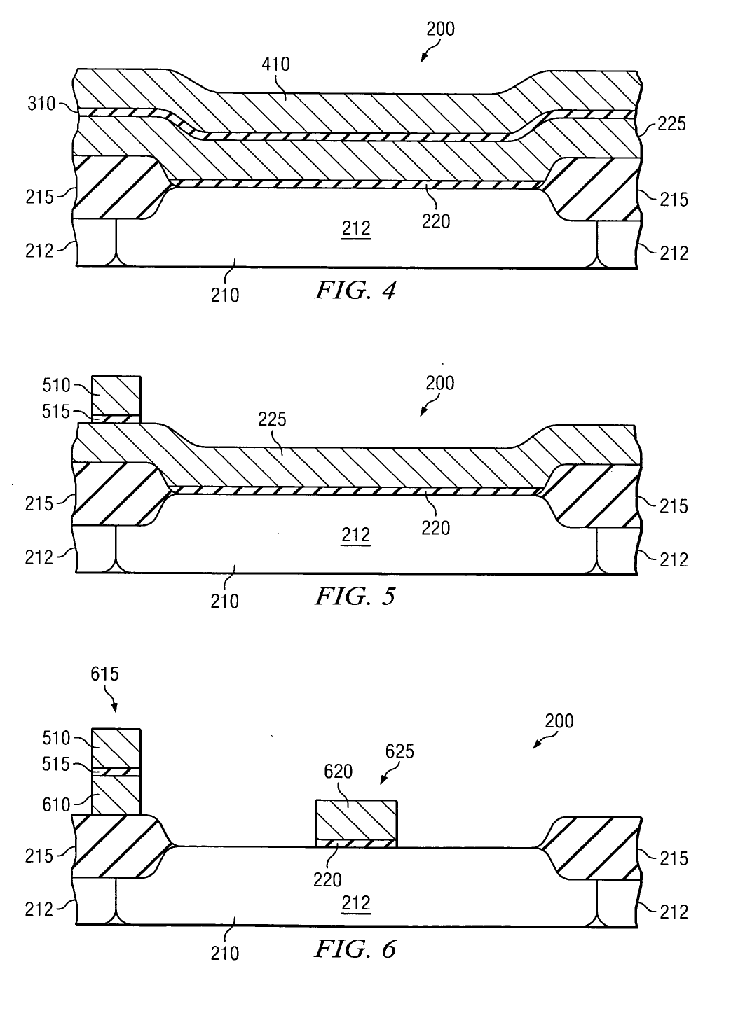

Turning now to FIG. 4, there is illustrated a partial sectional view of the microelectronics device 200 of FIG. 3 following the deposition and doping of a second layer 410 from which the second electrode of the capacitor will be formed. In an advantageous embodiment, the second layer 410 is amorphous silicon. This will particularly be the case when the gate layer 225 is polysilicon. Alternatively, the second layer 410 may comprise polysilicon in those embodiments where the gate layer 225 is amorphous silicon. However, as mentioned above, both the gate layer 225 and second layer 410 may comprise amorphous silicon in certain embodiments.

In those embodiments where the second layer 410 comprises amorphous silicon, the second layer 410 may be formed, for example, by flowing silane gas over the microelectronic device substrate 200 at a temperature ranging from about 510 degrees centigrade to about 580 degrees centigrade. In a preferred embodiment, the deposition temperature ranges from about 510 degrees centigrade to about 540 degrees centigrade, and it has been found that this range of deposition temperatures provides a device with improved linearity over other deposition temperature. Those skilled in the art understand that other deposition parameters, such as flow rates and pressures may vary as well.

The second layer 410 may be implanted with the same dopant type used to form the gate layer 225. As mentioned above, the following processing conditions can also be used to form the gate layer 225 in those embodiments where the gate layer 225 comprises amorphous silicon. In one embodiment, the dopant dosage of the amorphous layer 410 is greater than about 3e15 atoms/cm² and is conducted at an implant power greater than about 30 keV. However, in a more specific embodiment, the dopant dosage ranges from about 3e15 atoms/cm² to about 1.5e16 atoms/cm² and at an implant power ranging from about 30 keV to about 90 keV.

In one embodiment, the dopant is activated at the same time that transistor source/drain dopants are activated. However, in other embodiments, the dopant may be activated following the implant process but before the source/drain activation. In even more specific embodiments, however, the dopant dosage is about 3e15 atoms/cm² conducted at an implant power of about 30 keV, or the dopant dosage may be 6e15 atoms/cm² conducted at an implant power of 60 keV.

Turning now to FIG. 5, there is illustrated a partial section view of the microelectronics device 200 of FIG. 4, following the patterning of the second layer 510 and the capacitor dielectric layer 515 to form an upper electrode 510 and capacitor dielectric 515 of a partially completed capacitor. The second layer 510 and capacitor dielectric layer 515 may be patterned using a conventional lithography and photoresist processes. It is then etched to achieve the structure shown in FIG. 5.

In one embodiment, the second layer 510 and capacitor dielectric layer are etched using a well known reactive ion etching process that can be easily controlled to stop on the gate layer 225; however, other etching processes known to those skilled in the art may also be used. Following the etching of the second layer 510, the appropriate clean steps are conducted. Since one skilled in the art is very familiar with such patterning, etching, and cleaning processes, the details of these processes have not been discussed here.

Referring now to FIG. 6, there is illustrated a partial section view of the microelectronics device 200 of FIG. 5, after the patterning of the gate layer 620 to form a first electrode 610 of a completed capacitor 615 and gate 620 of a partially completed transistor 625. Conventional patterning and etching processes can be used to form the first electrode 610 and the gate 620. The microelectronics device 200 is then cleaned and subsequent processing steps are conducted to form conventional lightly doped drain (LDD) oxide spacers and capping layers (not shown) for the gate structures.

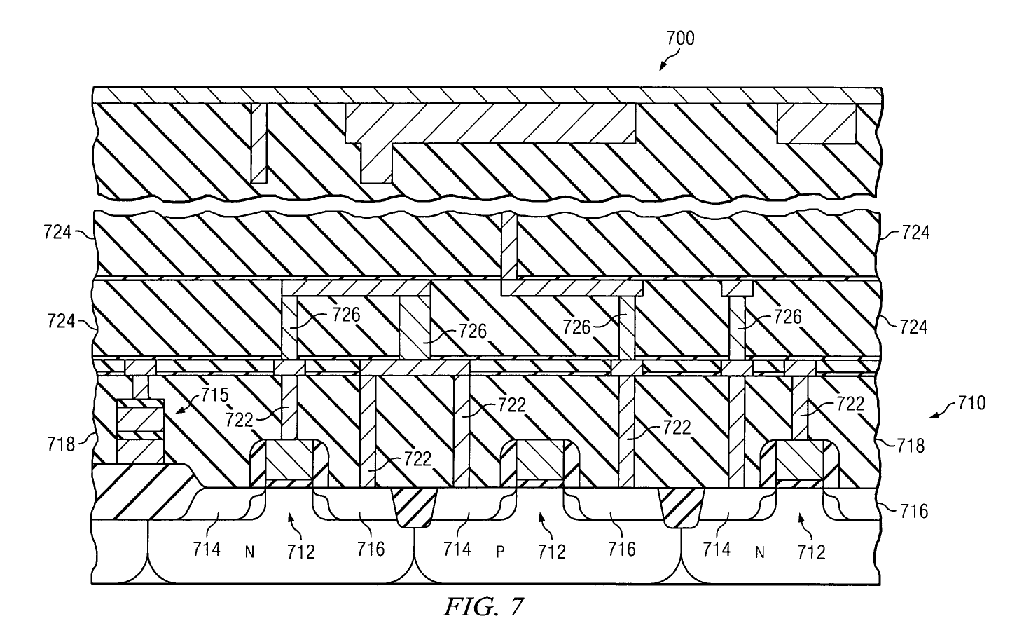

In those devices that require LDD regions, the appropriate dopant dosage is used to form conventional LDD regions for both the P-type and N-type regions when a complementary device configuration is intended. The LDD regions are not shown in FIG. 6 but are generally included in FIG. 7, as discussed below. After formation of the oxide spacers and implant of the respective source/drain regions, an anneal is conducted to activate the dopants in not only the source/drain regions, but also the dopant in the gate 620. In those embodiments where the activation of the dopant in the second electrode 510 is delayed as mentioned above, the anneal that activates the dopant in the gate 620 also activates the dopant in the second electrode 510. The anneal, in one embodiment, is conducted for 30 minutes and at a temperature of about 870 degrees centigrade in the presence of nitrogen, which is sufficient to change any amorphous material present in the capacitor 615 into a crystalline silicon. However, since the implant originally occurred in an amorphous material, the above-discussed advantages can be realized.

By way of further illustration of an advantageous embodiment provided by the present invention, attention is now directed to FIG. 7, which is a partial sectional view of a multi-layered integrated circuit 700 design. The integrated circuit 700 comprises an active level 710 that includes conventionally formed transistors 712 that have source/drains 714, 716, respectively, including LDD regions, and in some instances halo regions both of which are not designated for simplicity, and a linear capacitor 715, as provided by the present invention. Located directly over the transistors 712 is a pre-metal dielectric layer 718 in which interconnects 722 are located. The interconnects 722 may comprise copper, while pre-metal dielectric layer 718 may comprise phosphorous silicate glass and fluorosilicate glass, respectively. It should be understood that while FIG. 7 does not illustrate them, the integrated circuit 700 includes the appropriate barrier layers in the interconnects and between the various dielectric layers.

Interlevel dielectric layers 724 are sequentially shown over the pre-metal dielectric layer 718, and interconnect structures 726 are formed within those various interlevel dielectric layers 724. As with previous layers, the interconnects may comprise copper or other conductive metals, such as aluminum, and the interlevel dielectric layers 726 may comprise fluorosilicate glass.

Again, it should be understood that FIG. 7 is intended to be a general representation of an integrated circuit only and that the layout and design of the circuit may vary significantly, depending on the intended electrical application. For instance, in RF and analog applications, the integrated circuit 700 may include deep implanted regions, such as a Diffusion Under Field dielectric isolation DUF) region, etc., or it may be a bipolar device. What ever the layout scheme, it should be understood that such layout schemes are well within the scope of the present invention.

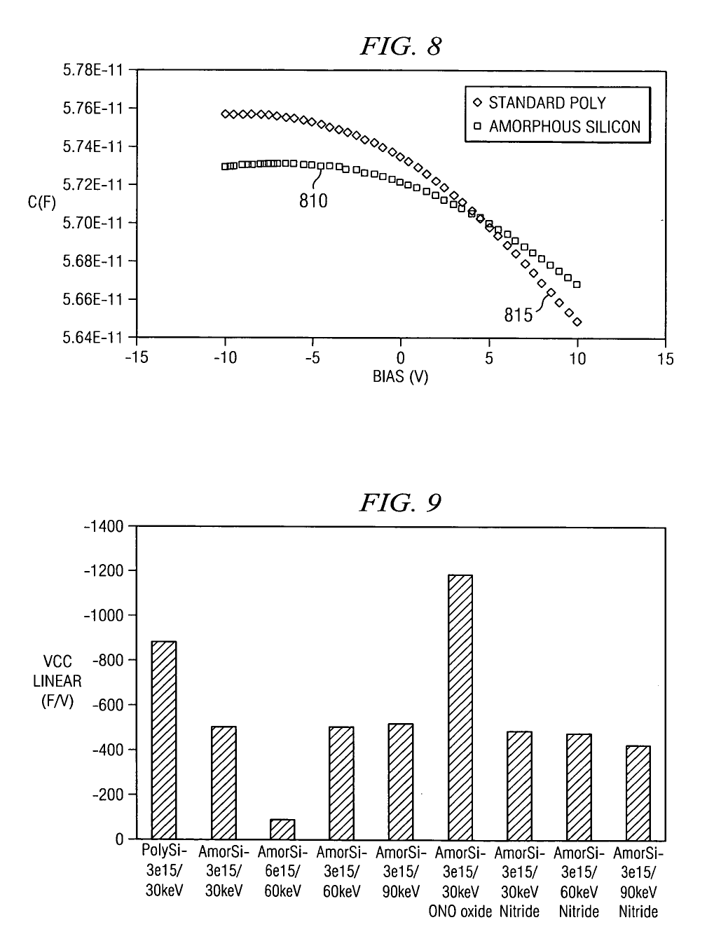

When the dopants are implanted into amorphous silicon versus polysilicon, the non-crystalline nature of the amorphous silicon does not include the significant number of grain boundaries that are present in polysilicon material. Thus, the dopant is less trapped, which makes more of the dopant available for activation during the subsequent annealing step. The implanting of the dopants into amorphous silicon versus polysilicon results in a more uniform activation of the dopants and provides less resistance and a more non-dispersive, linear capacitor that has a flatter capacitance with respect to voltage, as illustrated in the graph of FIG. 8. Moreover, the increased activation of the dopant reduces the depletion of the polysilicon plates which improves the linearity.

FIG. 8 is a graph of the capacitance versus voltage of a capacitor constructed using prior art processes and materials and a capacitor made in accordance with an embodiment of the present invention. Line 810 represents the capacitance/voltage data attributable to the device that includes at least one electrode made from an amorphous material, which in the test sample is the second electrode, and line 815 represents the capacitor wherein both electrodes are conventionally constructed of polysilicon. As seen in FIG. 8, line 810 presents a much flatter curve indicating a more linear and non-dispersive capacitor when compared to line 815 that indicates more variance in the capacitance over the same voltage range, thereby indicating a less linear and more dispersive capacitor. Thus, the present invention provides distinct advantages over conventional polysilicon electrodes.

In further support of the advantages associated with the present invention, the linear voltage capacitance coefficients (VCC) of different capacitors having at least one electrode fabricated from amorphous silicon using differing dopant dosages and implant powers were compared to a conventional capacitor having electrodes made only from polysilicon; the results of which are shown in FIG. 9. For general reference, unless otherwise indicated in FIG. 9, the capacitor dielectrics comprised silicon dioxide and had a thickness of 25 nm. Those capacitors having a silicon nitride dielectric layer had a thickness of 35 nm, and the capacitor wherein the capacitor dielectric was an ONO stack, the respective thicknesses of each layer was 6, 7.5 and 7.5 nm.

As seen from FIG. 9, the VCC of the capacitor whose electrodes were fabricated only from polysilicon is significantly higher than the VCC of the capacitors that had at least one electrode fabricated from amorphous silicon, with the unexpected exception of the capacitor that had an oxygen-nitride-oxygen (ONO) layered capacitor dielectric. Moreover, it was unexpectedly found that the VCC of a given capacitor improved with implanting the dopants at certain dosages and implant powers as evidenced by the data presented in FIG. 9. It should be noted that there was a much stronger dependency on dose compared to power. Generally, however, it can be seen from FIG. 9 that a more linear and non-dispersive capacitor can be achieved by fabricating at least one of the capacitor's electrodes from amorphous silicon. In fact the presence of an electrode fabricated from amorphous silicon improved the VCC by approximately 40%.

Therefore, it is readily apparent from the foregoing that the present invention provides a capacitor having improved VCC linearity and that is more comparable to metal capacitors but without the disadvantages discussed above. Because the amorphous silicon can be deposited at the gate level, the present invention also provides improved integration into standard CMOS process flows. Additionally, because the capacitor can be manufactured in the front end, their incorporation have minimal impact on the area required for metal interconnects.

Although the present invention has been described in detail, one who is of ordinary skill in the art should understand that they can make various changes, substitutions, and alterations herein without departing from the scope of the invention.

What is claimed is:

1. A method of fabricating a capacitor, comprising:
forming a first electrode;
placing a dielectric over the first electrode; and
locating a second electrode over the dielectric wherein at least one of the first or second electrodes is formed from a doped amorphous silicon.

2. The method as recited in claim 1, wherein the second electrode is doped amorphous silicon.

3. The method as recited in claim 1, wherein both the first and second electrodes are doped amorphous silicon.

4. The method as recited in claim 1, wherein locating includes doping at least one of the first or second electrodes at a dopant dosage ranging from about 3e15 atoms/cm² to about 1.5e16 atoms/cm².

5. The method as recited in claim 1, wherein locating includes doping at least one of the first or second electrodes at a power ranging from about 30 keV to about 90 keV.

6. The method as recited in claim 1, wherein the dielectric comprises silicon oxide or silicon nitride.

7. The method as recited in claim 1, wherein locating includes doping at least one of the first or second electrodes at a dosage of about 6e 15 atoms/cm² and at a power of 60 keV.

8. The method as recited in claim 1, wherein locating includes doping at least one of the first or second electrodes at a dosage of about 3e15 atoms/cm² and at a power of 30 keV.

9. The method as recited in claim 1 further including forming at least one of the first or second electrodes of amorphous silicon at temperature of about 580 degrees centigrade or less.

10. The method as recited in claim 9, wherein the temperature ranges from about 510 degrees centigrade to about 540 degrees centigrade.

11. A method of fabricating an integrated circuit, comprising:
forming transistors over a microelectronics substrate;
placing capacitors over the microelectronics substrate, including;
forming a first electrode;
placing a capacitor dielectric over the first electrode; and
locating a second electrode over the dielectric wherein at least one of the first or second electrodes is formed from a doped amorphous silicon;
depositing dielectric layers over the transistors and capacitors; and
forming interconnects within the dielectric layers to interconnect the transistors and the capacitors to form an operative integrated circuit.

12. The method as recited in claim 11, wherein the second electrode is doped amorphous silicon.

13. The method as recited in claim 12, wherein the capacitors and transistors are located on a same level of the integrated circuit.

14. The method as recited in claim 11, wherein locating includes doping at least one of the first or second electrodes at a dopant dosage ranging from about 3e15 atoms/cm² to about 1.5e16 atoms/cm².

15. The method as recited in claim 11, wherein locating includes doping at least one of the first or second electrodes at a power ranging from about 30 keV to about 90 keV.

16. The method as recited in claim 11, wherein the capacitor dielectric comprises silicon oxide or silicon nitride.

17. The method as recited in claim 11, wherein locating includes doping at least one of the first or second electrodes at a dosage of about 6e15 atoms/cm² and at a power of 60 keV.

18. The method as recited in claim 11, wherein placing includes doping at least one of the first or second electrodes at a dosage of about 3e15 atoms/cm² and at a power of 30 keV.

19. The method as recited in claim 11 further including forming at least one of the first or second electrodes of amorphous silicon at temperature of about 580 degrees centigrade or less.

20. The method as recited in claim 19, wherein the temperature ranges from about 510 degrees centigrade to about 540 degrees centigrade.
